(19) United States
(12) Patent Application Publication
(10) Pub. No.: US 2026/0297706 A1
(43) Pub. Date: Oct. 1, 2026

(54) ALLOY MATERIAL AND CONTACT PROBE

(71) Applicant: NHK Spring Co., Ltd., Yokohama-shi (JP)

(72) Inventors: Masayuki Ainoya, Kochi (JP); Tomohiro Kubota, Kochi (JP); Jun Nitta, Kanagawa (JP); Kosuke Shibairi, Kanagawa (JP); Kazuya Soma, Kanagawa (JP); Futa Sasaki, Kanagawa (JP); Ryohei Inohara, Kanagawa (JP)

(73) Assignee: NHK Spring Co., Ltd., Yokohama-shi (JP)

(21) Appl. No.: 19/571,912

(22) Filed: Mar. 19, 2026

(30) Foreign Application Priority Data
Mar. 27, 2025 (JP) 2025-053805

(51) Int. Cl. C22C 5/06; G01R 1/067

(52) U.S. Cl. CPC C22C 5/06; G01R 1/06755

(57) ABSTRACT

An alloy material includes: silver (Ag); copper (Cu); platinum (Pt); at least one of ruthenium (Ru) or rhenium (Re) in a total amount ranging from 0.05 wt % or more and 1.0 wt % or less; and the balance unavoidable impurities, wherein X, Y, and Z are within a composition range, including values on line segments, surrounded by line segments connecting points of following compositions (X=75, Y=5, Z=20), (X=20, Y=5, Z=75), (X=5, Y=20, Z=75), (X=5, Y=60, Z=35), and (X=75, Y=13, Z=12), where a weight ratio of silver (Ag) is X % by weight, a weight ratio of copper (Cu) is Y % by weight, and a weight ratio of platinum (Pt) is Z % by weight.

This application is based upon and claims the benefit of priority of the prior Japanese Patent Application No. 2025-053805, filed on Mar. 27, 2025, the entire contents of which are incorporated herein by reference.

### BACKGROUND

The present disclosure relates to an alloy material and a contact probe.

In the related art, when conduction state inspection or operation characteristic inspection is performed on an inspection target such as a semiconductor integrated circuit or a liquid crystal panel, a conductive contact probe is used to establish electrical connection between the inspection target and a signal processing device having a circuit board that outputs an inspection signal. In order to perform conduction state inspection or operation characteristic inspection accurately, it is required to reliably input and output an inspection signal via the contact probe.

The contact probe is used by repeatedly bringing it into contact with the target of inspection such as a semiconductor integrated circuit or a liquid crystal display device. Therefore, the material used for the contact probe is required to have durability. As a material for enhancing durability, a high hardness material containing platinum (Pt) as a main component and containing 0.1 to 14% of ruthenium (Ru), 0.1 to 14% of iridium (Ir), 0.1 to 5.0% of silver (Ag), and 0.1 to 5.0% of copper (Cu) in terms of weight ratio is known (see, for example, JP 2006-70337 A).

### SUMMARY

Contact probes are manufactured by casting. At this time, during the crystal growth process in casting, dendrites which are resinous crystals are formed, and no molten metal is supplied to the gaps between the dendrites, which results in the formation of gaps called shrinkage cavities. The shrinkage cavities cause casting defects in the manufactured product.

There is a need for an alloy material and a contact probe capable of reducing casting defects.

According to one aspect of the present disclosure, there is provided an alloy material including: silver (Ag); copper (Cu); platinum (Pt); at least one of ruthenium (Ru) or rhenium (Re) in a total amount ranging from 0.05 wt % or more and 1.0 wt % or less; and the balance unavoidable impurities, wherein X, Y, and Z are within a composition range, including values on line segments, surrounded by line segments connecting points of following compositions (X=75, Y=5, Z=20), (X=20, Y=5, Z=75), (X=5, Y=20, Z=75), (X=5, Y=60, Z=35), and (X=75, Y=13, Z=12), where a weight ratio of silver (Ag) is X % by weight, a weight ratio of copper (Cu) is Y % by weight, and a weight ratio of platinum (Pt) is Z % by weight.

### BRIEF DESCRIPTION OF THE DRAWINGS

FIG. 1 is a perspective view illustrating a configuration of a probe unit according to an embodiment;

FIG. 2 is a cross-sectional view illustrating a configuration of a main part of a probe unit according to an embodiment;

FIG. 3 is a diagram illustrating a content ratio of copper (Cu), silver (Ag), and platinum (Pt) in an embodiment;

FIG. 4 is a partial cross-sectional view illustrating a configuration of a main part of a probe unit at the time of inspecting a semiconductor integrated circuit;

FIG. 5 is a diagram illustrating a shape of an ingot for performing structure observation;

FIG. 6 is a diagram illustrating a CCD image for explaining defects due to an additive element;

FIG. 7 is a diagram illustrating an SEM image for explaining defects due to an additive element;

FIG. 8 is an enlarged view of a region R₁ illustrated in FIG. 7;

FIG. 9 is a diagram (part 1) illustrating a backscattered electron image and an element mapping image for explaining defects due to an additive element;

FIG. 10 is a diagram (part 2) illustrating a backscattered electron image and an element mapping image for explaining defects due to an additive element; and

FIG. 11 is a diagram illustrating a backscattered electron image and an element mapping image for explaining a powder shape of an additive element.

### DETAILED DESCRIPTION

Hereinafter, an embodiment for carrying out the present disclosure will be detailed with reference to the drawings. Note that the present disclosure is not limited to the following embodiment. In addition, each drawing referred to in the following description merely schematically illustrates a shape, a size, and a positional relationship to such an extent that the content may be understood, and thus the present disclosure is not limited only to the shape, the size, and the positional relationship illustrated in each drawing.

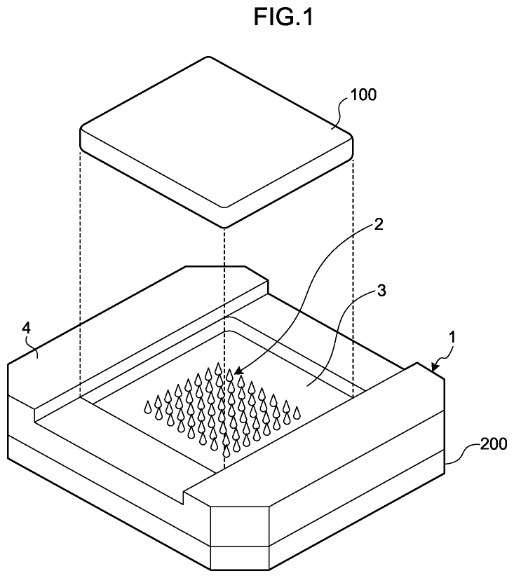

FIG. 1 is a perspective view illustrating a configuration of a probe unit according to an embodiment. A probe unit 1 illustrated in FIG. 1 is a device that is used when electrical characteristic inspection is performed on a semiconductor integrated circuit 100 as the target of inspection, and electrically connects the semiconductor integrated circuit 100 and a circuit board 200 that outputs an inspection signal to the semiconductor integrated circuit 100.

The probe unit 1 includes: a conductive contact probe 2 (hereinafter, simply referred to as a “probe 2”) that is in contact with electrodes of the semiconductor integrated circuit 100 and the circuit board 200, which are two objects to be contacted that are different from each other, at both ends of the probe 2 in the longitudinal direction; a probe holder 3 that accommodates and holds the plurality of probes 2 according to a predetermined pattern; and a holder member 4 that is provided around the probe holder 3 and prevents occurrence of positional deviation of the semiconductor integrated circuit 100 that comes into contact with the plurality of probes 2 at the time of inspection.

In the present embodiment, the electrode of the semiconductor integrated circuit 100 is a ball grid array (BGA) formed using solder.

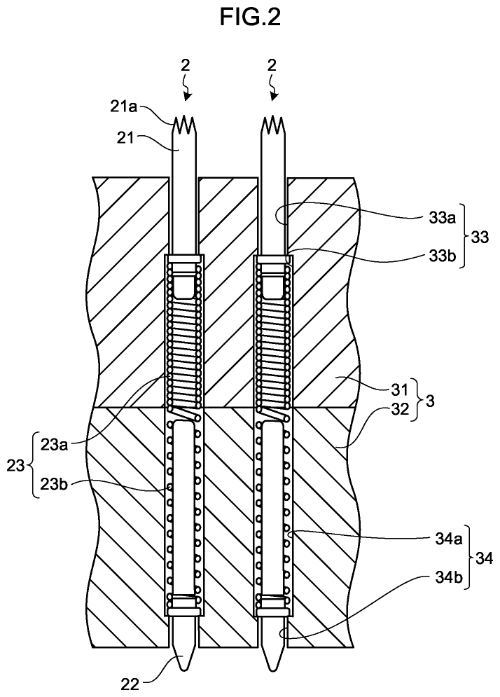

FIG. 2 is a cross-sectional view illustrating a configuration of a main part of a probe unit according to an embodiment. The probe 2 is formed using a conductive material, and includes a first plunger 21 that comes into contact with the electrode of the semiconductor integrated circuit 100 when the semiconductor integrated circuit 100 is inspected, a second plunger 22 that comes into contact with the electrode of the circuit board 200 including an inspection circuit, and a coil spring 23 that is provided between the first plunger 21 and the second plunger 22 to connect the first plunger 21 and the second plunger 22 so as to freely extend and retract. In FIG. 2, the first plunger 21, the second plunger 22, and the coil spring 23 constituting the probe 2 have the same axis. That is, the central axes of the first plunger 21, the second plunger 22, and the coil spring 23 are located on the same straight line. It is noted that the “same axis” includes a deviation due to distortion of individual members, manufacturing errors, and the like. When the semiconductor integrated circuit 100 is brought into contact with the probe 2, the coil spring 23 expands and contracts in the axial direction to soften impact on the electrode of the semiconductor integrated circuit 100, and also applies a load to the semiconductor integrated circuit 100 and the circuit board 200.

The first plunger 21 includes a distal end 21a having a tapered tip shape and coming into contact with the electrode of the semiconductor integrated circuit 100. The first plunger 21 may move in the axial direction in response to the expansion and contraction action of the coil spring 23, is biased in the direction of the semiconductor integrated circuit 100 by the elastic force of the coil spring 23, and comes into contact with the electrode of the semiconductor integrated circuit 100.

In the present embodiment, the distal end 21a will be described as having a crown shape with a plurality of claw portions, but may have another shape such as a cone shape or a spherical shape.

The first plunger 21 is formed using an alloy material.

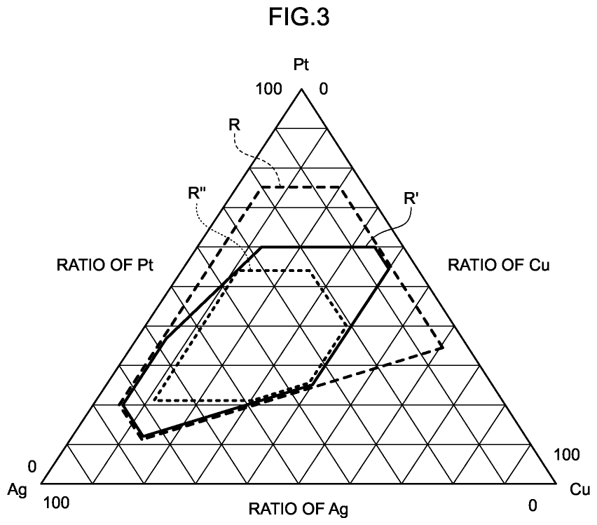

FIG. 3 is a diagram illustrating a content ratio of copper (Cu), silver (Ag), and platinum (Pt) in an embodiment. As the alloy material forming the first plunger 21, Ag—Cu—Pt has a composition to be a combination in a region R illustrated in FIG. 3.

Specifically, in the alloy material, when the weight ratio of silver (Ag) is X % by weight, the weight ratio of copper (Cu) is Y % by weight, and the weight ratio of platinum (Pt) is Z % by weight, X, Y, and Z are within a composition range (region R), including values on line segments, surrounded by line segments connecting points of the following compositions (X=75, Y=5, Z=20), (X=20, Y=5, Z=75), (X=5, Y=20, Z=75), (X=5, Y=60, Z=35), and (X=75, Y=13, Z=12), and the balance contains unavoidable impurities. In this composition range, preferably, X, Y, and Z are within a range (region R′) surrounded by line segments connecting points of the following compositions (X=75, Y=13, Z=12), (X=75, Y=5, Z=20), (X=60, Y=5, Z=35), (X=27, Y=13, Z=60), (X=5, Y=35, Z=60), (X=5, Y=40, Z=55), and (X=35, Y=40, Z=25). More preferably, X, Y, and Z are within a range (region R″) surrounded by line segments connecting points of the following compositions (X=68, Y=11, Z=21), (X=35, Y=11, Z=54), (X=21, Y=25, Z=54), (X=21, Y=39, Z=40), (X=36, Y=39, Z=25), and (X=48, Y=31, Z=21).

Here, when the alloy material contains more than 75 wt % of Ag, the amount of precipitated phases decreases and the hardness decreases. On the other hand, when Ag is less than 5 wt %, the resistance value increases and the resistance to Sn reaction decreases.

When the alloy material contains more than 60 wt % of Cu, the alloy material is easily oxidized at a high temperature (here, about 175° C.), which may cause appearance defects. On the other hand, when Cu is less than 5 wt %, the amount of precipitated phases decreases and the hardness decreases.

In addition, as an alloy material, Pt has a higher resistance value than Ag and Cu. Accordingly, when the alloy material contains more than 75 wt % of Pt, the resistance value as the alloy material increases. On the other hand, when Pt is less than 10 wt %, the amount of precipitated phases decreases and the hardness decreases.

Further, the alloy material contains ruthenium (Ru) and/or rhenium (Re) in a total amount ranging from 0.05 wt % or more and 1.0 wt % or less in addition to the Ag—Cu—Pt. When the total amount of Ru and Re is less than 0.05 wt %, the amount of nucleus, to be described later, generated is small, and the effect of reducing dendrite formation may not be achieved. When the total amount of Ru and Re is more than 1.0 wt %, the amount of nucleus generated is excessive and functions as an inclusion, which may lead to an increase in resistance value of the alloy material and a decrease in workability.

Further, the alloy material may contain at least one of an additive element group consisting of nickel (Ni), cobalt (Co), and chromium (Cr) in a range of 1.0 wt % or more and 20 wt % or less in total and/or contain at least one of an additive element group consisting of tungsten (W), titanium (Ti), aluminum (Al), and tin (Sn) in a range of 0.01 wt % or more and 3.0 wt % or less in total, although Ru and/or Re is added to the Ag—Cu—Pt and the balance contains unavoidable impurities. In the present embodiment, these additive elements improve the hardness of the alloy material. On the other hand, in a case where these additive elements are contained in an amount exceeding the upper limit value, the resistance value of the alloy material may increase.

Referring back to FIG. 2, the second plunger 22 has a tapered tip shape, and the tip comes into contact with the electrode of the circuit board 200. The second plunger 22 is formed using, for example, the same material as the first plunger 21 or another conductive material. The second plunger 22 may move in the axial direction in response to the expansion and contraction action of the coil spring 23, is biased in the direction of the circuit board 200 by the elastic force of the coil spring 23, and comes into contact with the electrode of the circuit board 200.

The coil spring 23 includes a tightly wound portion 23a attached to the proximal end side of the first plunger 21 in a closely contacting manner and a loosely wound portion 23b attached to the proximal end side of the second plunger 22 and wound at a predetermined interval. The coil spring 23 is formed by winding, for example, one conductive wire rod. Examples of the wire rod include a stainless steel wire and a piano wire.

The end of the tightly wound portion 23a is press-fitted to, for example, the proximal end side of the first plunger 21. On the other hand, the end of the loosely wound portion 23b is press-fitted to the proximal end side of the second plunger 22. The first plunger 21 and the second plunger 22 are joined to the coil spring 23 by a gripping force of the spring and/or soldering. The probe 2 expands and contracts in the axial direction in response to expansion and contraction of the loosely wound portion 23b.

The probe holder 3 is formed using an insulating material such as resin, machinable ceramic, or silicon, and is formed by stacking a first member 31 located on the upper surface side and a second member 32 located on the lower surface side in FIG. 2. The first member 31 and the second member 32 are formed with the same number of holder holes 33 and 34 for accommodating the plurality of probes 2, respectively, and the holder holes 33 and 34 for accommodating the probes 2 are formed so that their axes coincide with each other. The positions at which the holder holes 33 and 34 are formed are determined according to the wiring pattern of the semiconductor integrated circuit 100.

The holder holes 33 and 34 each have stepped hole shapes having different diameters along the penetrating direction. That is, the holder hole 33 includes a small diameter portion 33a having an opening in the upper end surface of the probe holder 3 and a large diameter portion 33b having a diameter larger than that of the small diameter portion 33a. On the other hand, the holder hole 34 includes a small diameter portion 34a having an opening in the lower end surface of the probe holder 3 and a large diameter portion 34b having a diameter larger than that of the small diameter portion 34a. The shapes of the holder holes 33 and 34 are determined according to the configuration of the probe 2 to be accommodated.

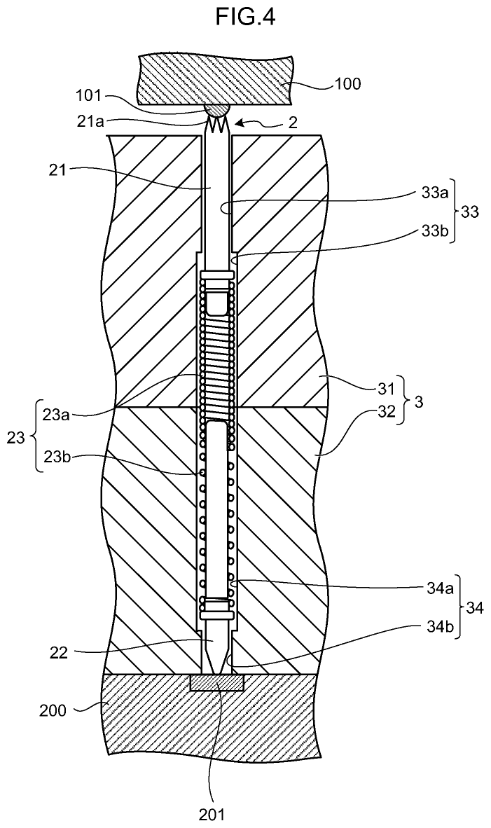

FIG. 4 is a diagram illustrating a state at the time of inspection of the semiconductor integrated circuit 100 using the probe holder 3. When the semiconductor integrated circuit 100 is inspected, the coil spring 23 is compressed along the longitudinal direction due to the contact load applied from the semiconductor integrated circuit 100 and the circuit board 200. The inspection signal supplied from the circuit board 200 to the semiconductor integrated circuit 100 at the time of inspection reaches a connection electrode 101 of the semiconductor integrated circuit 100 from an electrode 201 of the circuit board 200 via the second plunger 22, the tightly wound portion 23a, and the first plunger 21 of the probe 2.

In the present embodiment described above, a plunger is produced by using an alloy material in which, when the weight ratio of silver (Ag) is X % by weight, the weight ratio of copper (Cu) is Y % by weight, and the weight ratio of platinum (Pt) is Z % by weight, X, Y, and Z are within a composition range, including values on line segments, surrounded by line segments connecting points of the following compositions (X=75, Y=5, Z=20), (X=20, Y=5, Z=75), (X=5, Y=20, Z=75), (X=5, Y=60, Z=35), and (X=75, Y=13, Z=12), and, in addition to the Ag—Cu—Pt, ruthenium (Ru) and/or rhenium (Re) are contained in a total amount ranging from 0.05 wt % or more and 1.0 wt % or less and the balance contains unavoidable impurities. Using this alloy material may reduce defects due to casting at the time of producing the plunger. As for the contact probe, as long as at least a portion in contact with an object to be contacted, particularly a component (the first plunger 21 in this case) that repeatedly makes contact with and separates from the object to be contacted by repeated use is made of the alloy material described above, it is possible to achieve a contact probe with improved durability and few defects due to casting.

Hereinafter, examples according to the present disclosure will be described. Note that the present disclosure is not limited to the examples.

The structure observation was performed to examine how dendrite and casting cavity are formed due to an additive element.

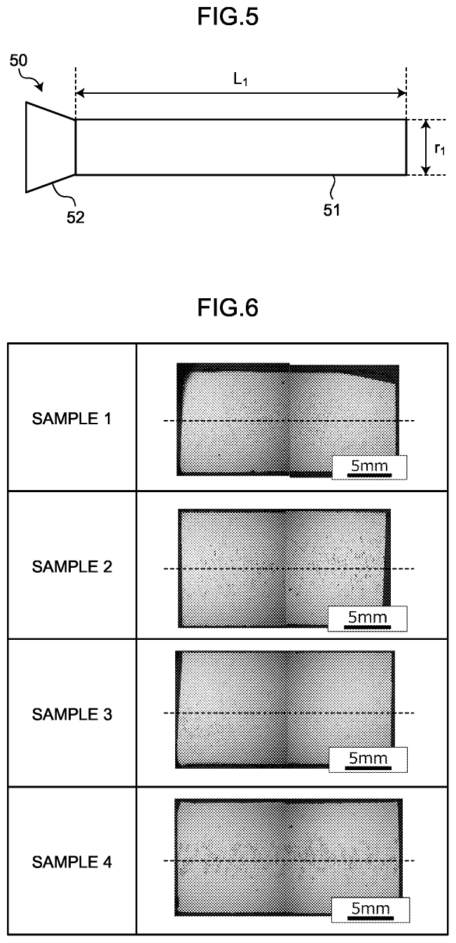

First, an ingot used for the structure observation will be described with reference to FIG. 5. FIG. 5 is a diagram illustrating a shape of the ingot for performing structure observation. An ingot 50 illustrated in FIG. 5 is obtained by performing heat treatment at 940° C. for one hour after casting, and includes a shaft portion 51 extending in a columnar shape, and a frustum-shaped riser 52 continuous with one end of the shaft portion 51 in the longitudinal direction. The diameter r₁ of the shaft portion 51 was 12 mm, and the length L₁ of the shaft portion 51 in the longitudinal direction was 165 mm.

As samples for structure observation, ingots 50 having compositions different from each other were prepared. The prepared samples are as follows.

Sample 1:0.5 wt % of iridium (Ir) added to 30 wt % of Ag-20 wt % of Cu-49.5 wt % of Pt

Sample 2:0.5 wt % of ruthenium (Ru) added to 30 wt % of Ag-20 wt % of Cu-49.5 wt % of Pt

Sample 3:0.5 wt % of rhenium (Re) added to 30 wt % of Ag-20 wt % of Cu-49.5 wt % of Pt

Sample 4:30 wt % of Ag-20 wt % of Cu-50 wt % of Pt (no additive element)

FIG. 6 is a diagram illustrating a charge coupled device (CCD) image for explaining defects due to an additive element. The CCD image illustrated in FIG. 6 is obtained by imaging a part of the cross-section of the shaft portion of each sample. Black spots observed in FIG. 6 indicate defects due to casting. For each sample, a region of 5 mm ×5 mm in the vicinity of the ingot center (see broken line in FIG. 6) was binarized using WinROOF2021 manufactured by MITANI CORPORATION to extract a defective portion, and the defect rate was determined. As the defect rate, the ratio of the area of the defective portion to the area of the entire region was calculated. In the CCD image illustrated in FIG. 6, the defect rate of each sample was as follows.
Sample 1 (Ir added): 7.1%
Sample 2 (Ru added): 3.6%
Sample 3 (Re added): 0.4%
Sample 4 (no addition): 11.1%

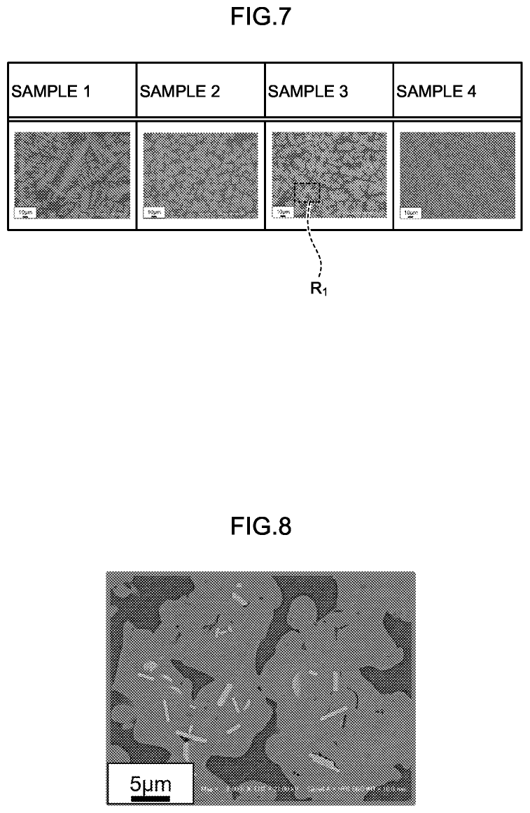

FIG. 7 is a diagram illustrating a scanning electron microscope (SEM) image for explaining defects due to an additive element. FIG. 8 is an enlarged view of a region R₁ illustrated in FIG. 7. The SEM image illustrated in FIG. 7 is obtained by imaging a part of the cross-section of the shaft portion of each sample at a magnification of 500 times, an acceleration voltage of 21.00 kV, and an operation distance of 10.00 mm using a scanning electron microscope (ZEISS Sigma) manufactured by ZEISS Corporation. In the SEM image, a gray part indicates an α phase (Pt-rich), a black part indicates a β phase (Ag-rich), and a white part indicates Re (see FIG. 8). As illustrated in FIG. 7, it may be seen that Sample 1 to which Ir is added has a coarse dendrite structure. In addition, it is found that a dendrite structure is also formed in Sample 4 with no additive elements. On the other hand, in Samples 2 and 3 to which Ru and Re are added respectively, it is found that formation of a dendrite structure is reduced. In Sample 3 to which Re is added, as illustrated in FIG. 8, it is found that a rod-like structure (Re) is included in the α phase.

Subsequently, the distribution and segregation of the additive element were observed using the ingot of each sample. For the image used for the observation, a backscattered electron image was acquired by X-ray analysis (SEM-EDX) using energy dispersive X-ray spectrometry (EDS), and a mapping image for the additive element was generated using an electron probe micro analyzer (EPMA). For EDS, XFlash 5010 (manufactured by Bruker) was used, and for EPMA, JXA-8530F (manufactured by JEOL Ltd.) was used.

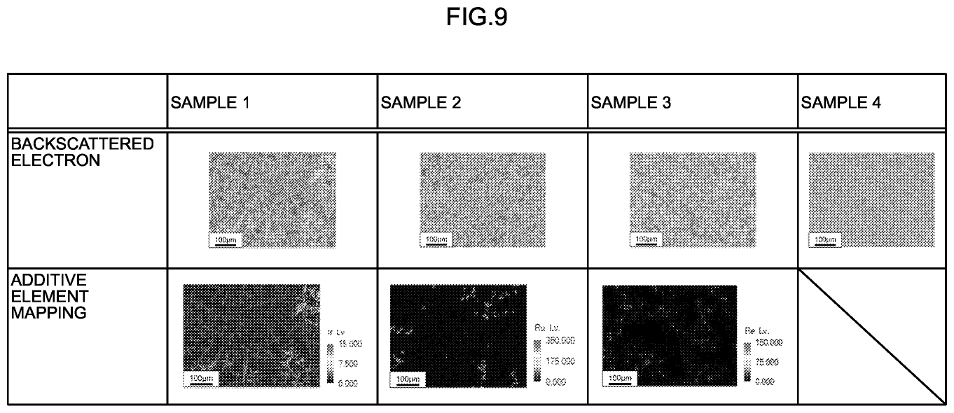

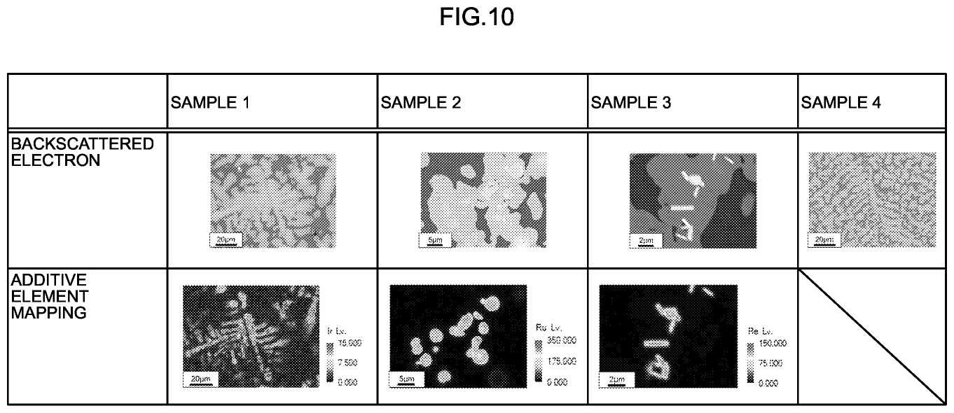

FIGS. 9 and 10 are diagrams each illustrating a backscattered electron image and an element mapping image for explaining defects due to an additive element. FIG. 9 illustrates a backscattered electron image and an element mapping image at low magnification. FIG. 10 illustrates a backscattered electron image and an element mapping image at high magnification. From FIGS. 9 and 10, it is found that Ir is solid-solved in the entire dendrite, and Re and Ru are fine and unevenly distributed. The addition of Re and Ru presumably serves as a nucleus of solidification to reduce the formation of dendrite.

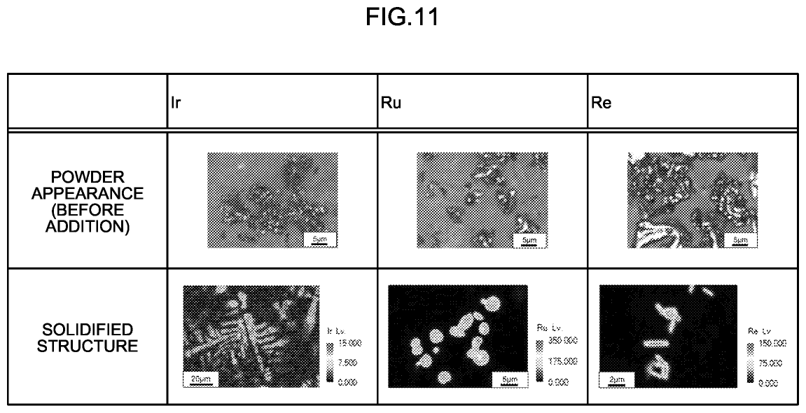

Further, the powder shape of the additive elements before being added to Ag—Cu—Pt was observed. FIG. 11 is a diagram illustrating a backscattered electron image (powder appearance) and an element mapping image (solidified structure) for explaining a powder shape of an additive element. As illustrated in FIG. 11, since the form differs between the powder and the solidified structure for each additive element, the additive elements dissolve during melting. Thereafter, Re and Ru presumably have finely precipitated during solidification and have served as a nucleus for the solidified structure.

As described above, Re and Ru, as additive elements, presumably serve as a nucleus for the solidified structure, reduce the formation of dendrite, which makes it possible to produce a cast article with a low defect rate. On the other hand, Ir is solid-solved in the entire dendrite, and the effect of reducing the formation of dendrite is presumably small, so that the defect rate is presumably higher than that for Re and Ru.

Although the embodiment for carrying out the present disclosure have been described so far, the present disclosure should not be limited only to the above-described embodiment. In the embodiment, the contact probe has been described as an example, but for example, the alloy material may be applied to any member for electric and electronic equipment that is brought into contact with a component containing Sn. At this time, it is only required that at least a part of the member in contact with the component is formed of the alloy material.

Further, the configuration of the probe 2 described in the embodiment is merely an example, and the alloy material described above may be applied to various types of probes conventionally known. For example, the present disclosure is not limited to the configuration including the plunger and the coil spring as described above, and a probe including a pipe member, a pogo pin, a wire probe that obtains a load by bending a wire in an arch shape, or a connection terminal (connector) that connects electrical contacts may be used.

As described above, the alloy material and the contact probe according to the present disclosure are suitable for reducing casting defects.

According to the present disclosure, it is possible to produce the effect of reducing casting defects.

All examples and conditional language recited herein are intended for pedagogical purposes of aiding the reader in understanding the disclosure and the concepts contributed by the inventor to further the art, and are not to be construed as limitations to such specifically recited examples and conditions, nor does the organization of such examples in the specification relate to a showing of the superiority and inferiority of the disclosure. Although the embodiment has been described in detail, it should be understood that the various changes, substitutions, and alterations could be made hereto without departing from the spirit and scope of the disclosure.

What is claimed is:

1. An alloy material comprising:
silver (Ag);
copper (Cu);
platinum (Pt);
at least one of ruthenium (Ru) or rhenium (Re) in a total amount ranging from 0.05 wt % or more and 1.0 wt % or less; and
the balance unavoidable impurities, wherein
X, Y, and Z are within a composition range, including values on line segments, surrounded by line segments connecting points of following compositions (X=75, Y=5, Z=20), (X=20, Y=5, Z=75), (X=5, Y=20, Z=75), (X=5, Y=60, Z=35), and (X=75, Y=13, Z=12), where a weight ratio of silver (Ag) is X % by weight, a weight ratio of copper (Cu) is Y % by weight, and a weight ratio of platinum (Pt) is Z % by weight.

2. The alloy material according to claim 1, wherein
X, Y, and Z are within a composition range, including values on line segments, surrounded by line segments connecting points of following compositions (X=75, Y=13, Z=12), (X=75, Y=5, Z=20), (X=60, Y=5, Z=35), (X=27, Y=13, Z=60), (X=5, Y=35, Z=60), (X=5, Y=40, Z=55), and (X=35, Y=40, Z=25).

3. The alloy material according to claim 2, wherein
X, Y, and Z are within a composition range, including values on line segments, surrounded by line segments connecting points of following compositions (X=68, Y=11, Z=21), (X=35, Y=11, Z=54), (X=21, Y=25, Z=54), (X=21, Y=39, Z=40), (X=36, Y=39, Z=25), and (X=48, Y=31, Z=21).

4. The alloy material according to claim 1, comprising:
at least one of an additive element group consisting of nickel (Ni), cobalt (Co), or chromium (Cr) in a range of 1.0 wt % or more and 20 wt % or less in total;
and/or
at least one of an additive element group consisting of tungsten (W), titanium (Ti), aluminum (Al), or tin (Sn) in a range of 0.01 wt % or more and 3.0 wt % or less in total.

5. A contact probe comprising
a component formed of the alloy material according to claim 1.
